(19) United States
(12) Patent Application Publication
(10) Pub. No.: US 2012/0264257 A1
(43) Pub. Date: Oct. 18, 2012

(54) MOLD ARRAY PROCESS METHOD TO PREVENT EXPOSURE OF SUBSTRATE PERIPHERIES

(76) Inventors: Kuo-Yuan Lee, Kaohsiung (TW); Yung-Hsiang Chen, Kaohsiung (TW); Wen-Chun Chiu, Kaohsiung (TW)

(21) Appl. No.: 13/086,851

(22) Filed: Apr. 14, 2011

(51) Int. Cl. H01L 21/56

(52) U.S. Cl. 438/113; 257/E21.502

(57) ABSTRACT

Disclosed is a mold array process (MAP) method to prevent exposure of peripheries of substrate units where the major characteristic is to implement two kinds of encapsulating materials in the MAP method in mass production. A first encapsulating material for encapsulating chips is formed on a substrate strip by molding to continuously encapsulate the substrate units and the scribe lines between adjacent substrate units. Prior to forming a second encapsulating material, a plurality of cut grooves are formed along the scribing lines by pre-cutting processes to penetrate through the substrate strip but without penetrating through the first encapsulating material and have such a width that a plurality of peripheries of the substrate units are exposed outside the scribing lines. Then, the second encapsulating material is filled into the cut grooves. Accordingly, the peripheries of the substrate units are still encapsulated with the remains of the second encapsulating material after singulation processes where the substrate units are singulated into individual semiconductor packages to prevent exposure of the peripheries of the substrate units.

### FIELD OF THE INVENTION

The present invention relates to a packaging method of manufacturing semiconductor packages in mass production, and more specifically to a mold array process method to prevent exposure of substrate peripheries.

### BACKGROUND OF THE INVENTION

Mold Array Process (MAP) is widely implemented in conventional semiconductor packaging technology which can provide lower cost in mass production. A substrate strip comprising a plurality of substrate units arranged in an array serves as chip carriers for a plurality of chips. After semiconductor packaging processes such as die attaching, wire bonding, etc, a molding compound larger than the substrate array is continuously disposed to encapsulate the substrate units and the scribe lines between the adjacent substrate units. Then the substrate is singulated along the scribe lines to obtain a plurality of individual semiconductor packages.

A conventional window type BGA semiconductor package manufactured by an MAP method is shown in FIG. 1 and a substrate strip used in the conventional MAP method is shown in FIG. 2. As shown in FIG. 1, a conventional semiconductor package 100 primarily comprises a substrate unit 113, a chip 120, and an encapsulant 130 where the chip 120 is disposed on the top surface 111 of the substrate unit 113. The substrate unit 113 further has a central slot 117 penetrating through from the top surface 111 to the bottom surface 112 with a plurality of electrodes 122 disposed on the active surface 121 of the chip 120 aligned to and exposed from the central slot 117 if the semiconductor package 100 is a window type BGA package. The electrodes 122 of the chip 120 are electrically connected to the substrate unit 113 by a plurality of bonding wires 150 passing through the central slot 117. The encapsulant 130 is disposed on the top surface 111 as well as inside the central slot 117 of the substrate unit 113 to encapsulate the chip 120 and the bonding wires 150. A plurality of solder balls 160 are disposed on the bottom surface 112 of the substrate unit 113 as the external terminals of the semiconductor package 100. However, with the existing technology of MAP, the encapsulant 130 can not fully encapsulate the sidewalls 116 of the substrate unit 113 where the core layers and metal traces of the substrate unit 113 would easily be exposed so that moisture would easily diffuse into the semiconductor package 100 leading to reliability issues.

As shown in FIG. 2, a plurality of substrate unit 113 are arranged in an array an in a conventional substrate strip 110 for the MAP method. A plurality of scribe lines 114 crisscrossing to each other are defined between the adjacent substrate units 113. As shown in FIG. 1 again, after die attaching and wire bonding, the substrate units 113 and the scribe lines 114 are encapsulated by the afore encapsulant 130 formed by molding processes where the encapsulant 130 disposed over the scribe lines 114 must be removed in the following processes such as singulation to form individual semiconductor packages 100. Therefore, the encapsulant 130 disposed over the scribe lines 114 does not exist in the final semiconductor packages 100. When the substrate units 113 are singluated along the scribe lines 114, the blades of singulation would cut through the encapsulant 130 and the substrate strip 110 to expose the sidewalls 116 of the substrate units 113 aligned with the cut surfaces of the encapsulant 130, i.e., the sidewalls 116 of the substrate units 113 can not be protected by the encapsulant 130. Therefore, after singulation, the plated traces and the core layer would be exposed from the sidewalls 116 of the substrate units 113 leading to poor moisture resistance and vulnerable for external disturbance. Moreover, the peripheral circuits on the substrate units 113 are easily be damaged by cutting tool during singulation processes leading to electrical short or open issues.

### SUMMARY OF THE INVENTION

The main purpose of the present invention is to provide a mold array process (MAP) method to prevent exposure of substrate peripheries where two different encapsulating materials are implemented during the MAP method along with the formation of cut grooves by pre-cutting at the scribe lines to resolve the conventional exposure of the sidewalls of substrates to avoid the exposure of metal traces and core layers at the peripheries of substrate units, and further to improve the resistant capability to the impact of environment such as oxidation, moisture, and others to improve the reliability of semiconductor packages.

According to the present invention, an MAP method to prevent exposure of substrate peripheries is disclosed. Firstly, a substrate strip is provided where the substrate strip has a top surface and an opposing bottom surface and includes a plurality of substrate units and a plurality of scribe lines defined between adjacent substrate units. After die bonding, a first encapsulating material is disposed on the top surface of the substrate strip to continuously encapsulate the substrate units and the scribe lines. Then, a pre-cutting step is performed where a plurality of cut grooves penetrating through the substrate strip are formed along the scribe lines without penetrating through the first encapsulating material. The width of each cut groove is wider than the width of the corresponding scribe line to make the substrate units have exposed peripheries outside the scribe lines. Then, a second encapsulating material is formed inside the cut grooves to encapsulate the peripheries of the substrate units. Finally, part of the first encapsulating material disposed on the scribe lines and part of the second encapsulating material disposed inside the cut grooves are removed by a singulation step to singulate the substrate unites into individual semiconductor packages with the peripheries of the substrate units still encapsulated by the second encapsulating material.

The mold array process (MAP) method to prevent exposure of substrate peripheries according to the present invention has the following advantages and effects:
1. Through the formation of a plurality of cut grooves penetrating through the substrate strip on the scribe lines after the first molding processes as a technical mean where the width of the cut grooves is wider than the width of the corresponding scribe lines, the remains of the second encapsulating material is still disposed inside the cut grooves to encapsulate the peripheries of the substrate units. Therefore, during singulation processes, cutting tool will only cut through the encapsulating materials without cutting at the substrate structure to resolve the conventional exposure of the sidewalls of substrates to avoid the exposure of metal traces and core layers at the peripheries of substrate units and to further improve the resistant capability to the impact of environment such as oxidation, moisture, and others to improve the reliability of semiconductor packages.
2. Through the formation of a plurality of cut grooves penetrating through the substrate strip on the scribe lines after the first molding processes as a technical mean, the substrate structure will not be damaged during singulation processes to avoid the deformation or shifting of internal circuitry inside the substrate due to the stresses caused by cutting through substrate during singulation processes.
3. Through the formation of a plurality of cut grooves penetrating through the substrate strip on the scribe lines after the first molding processes as a technical mean, the MAP method has been simplified by using the same post-mold curing step to completely cure two different encapsulating materials at the same time.

### DESCRIPTION OF THE DRAWINGS

FIG. 1 is a cross-sectional view of a conventional window type BGA semiconductor package fabricated by the conventional MAP method.

FIG. 2 is a partially top view of a substrate strip for the conventional MAP method.

FIGS. 3A to 3H are component cross-sectional views illustrating each processing step of an MAP method according to the first embodiment of the present invention.

FIG. 4 is a partial bottom view of a substrate strip after pre-cutting processes of the MAP method according to the first embodiment of the present invention.

FIGS. 5A to 5H are component cross-sectional views illustrating each processing step of another MAP method according to the second embodiment of the present invention.

FIG. 6 is a partial bottom view of a substrate strip provided in the MAP method according to the second embodiment of the present invention.

FIG. 7 is a partial bottom view of the substrate strip after a pre-cutting step of the MAP method according to the second embodiment of the present invention.

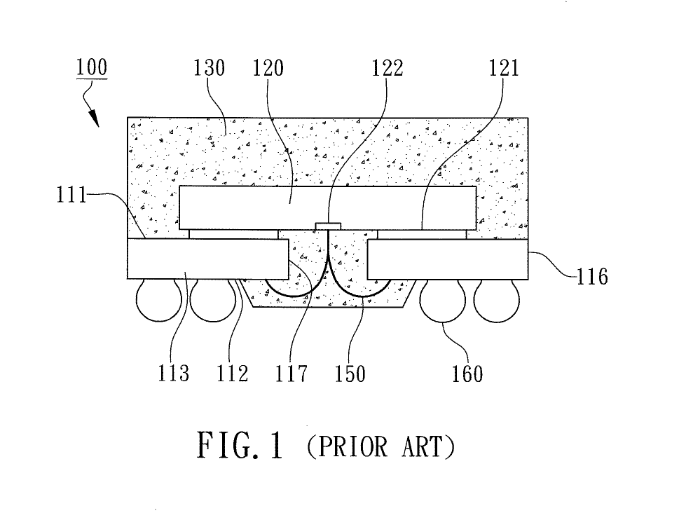

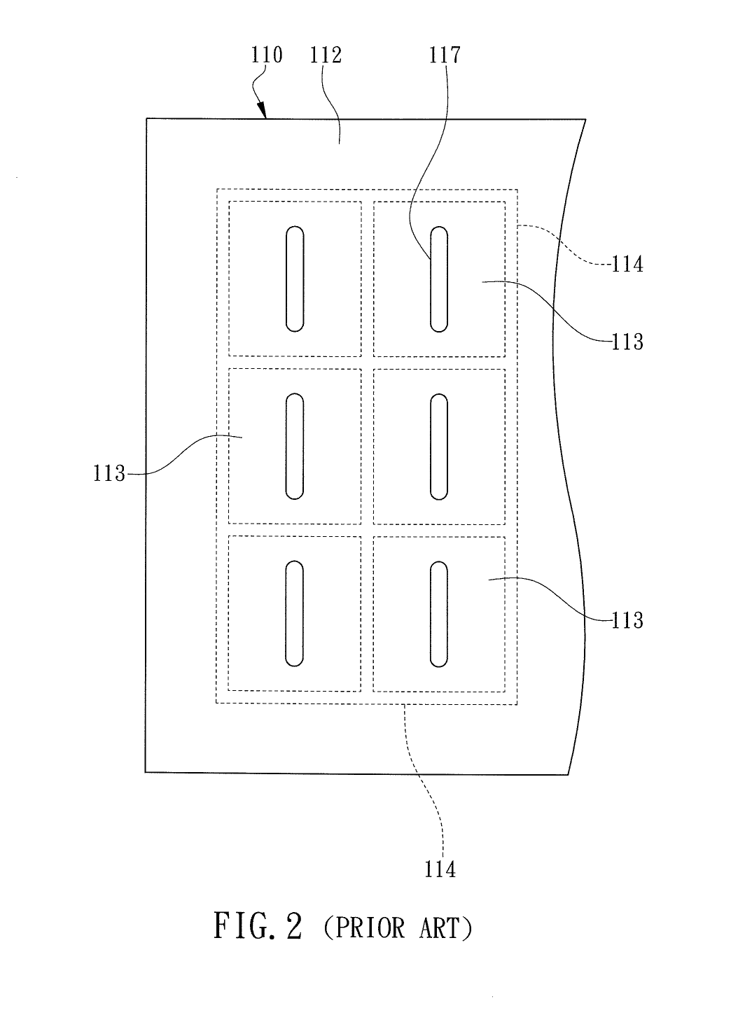

### DETAILED DESCRIPTION OF THE INVENTION

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

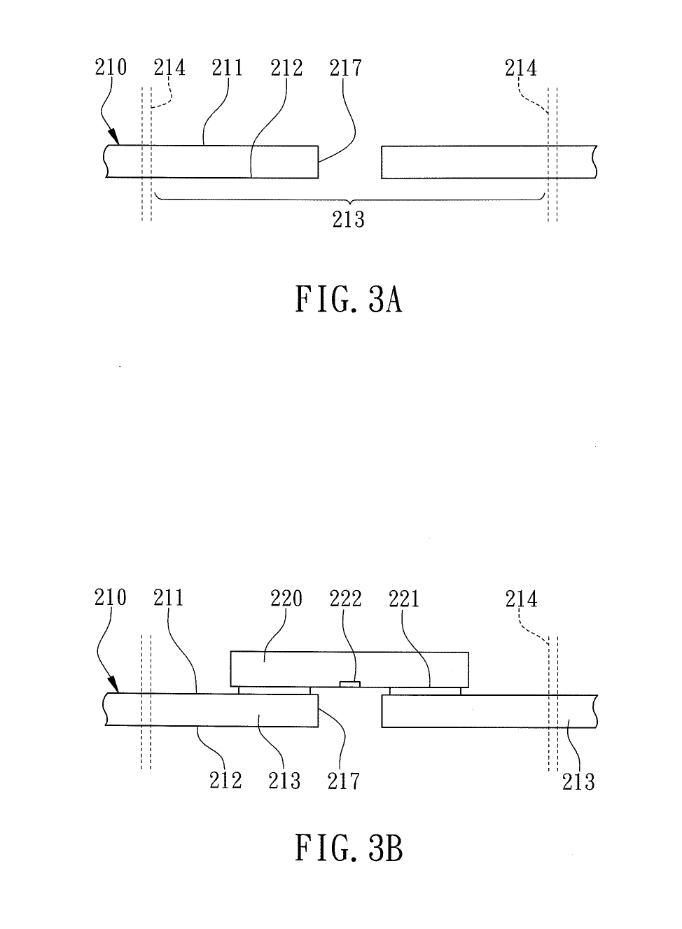

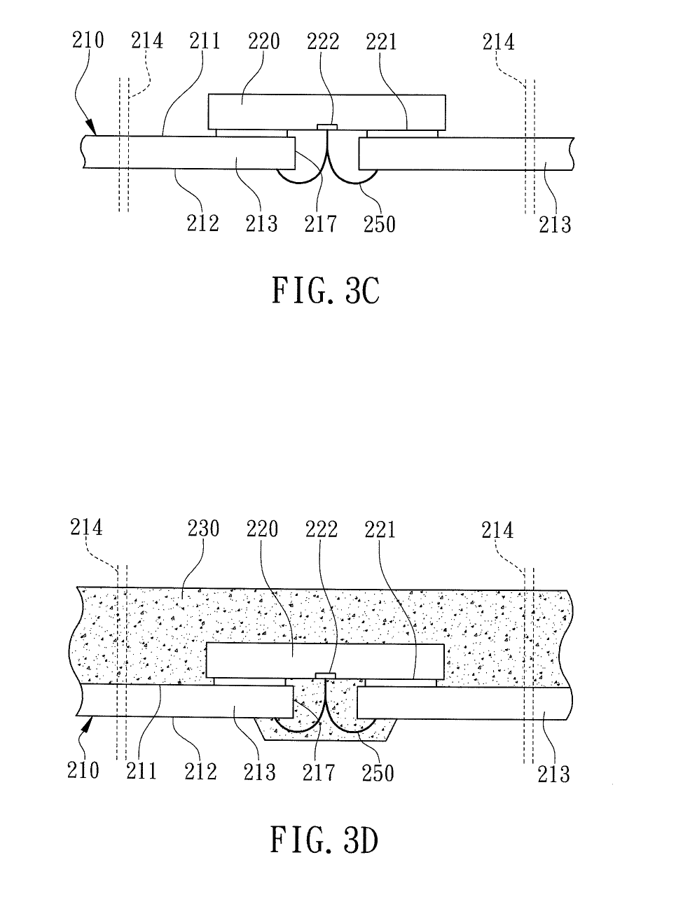

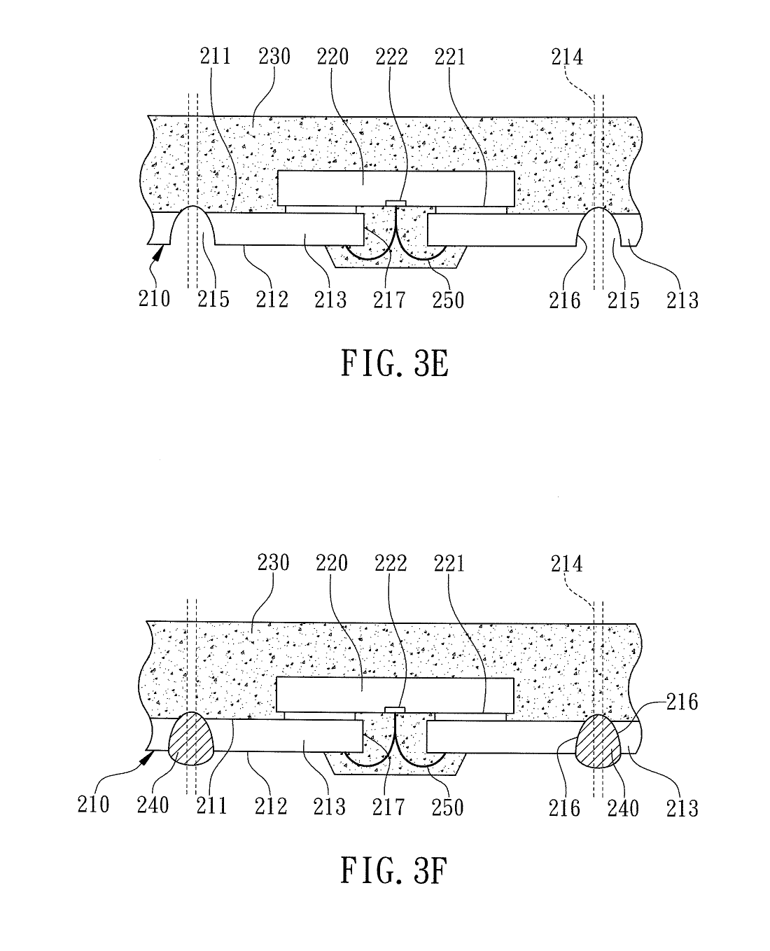

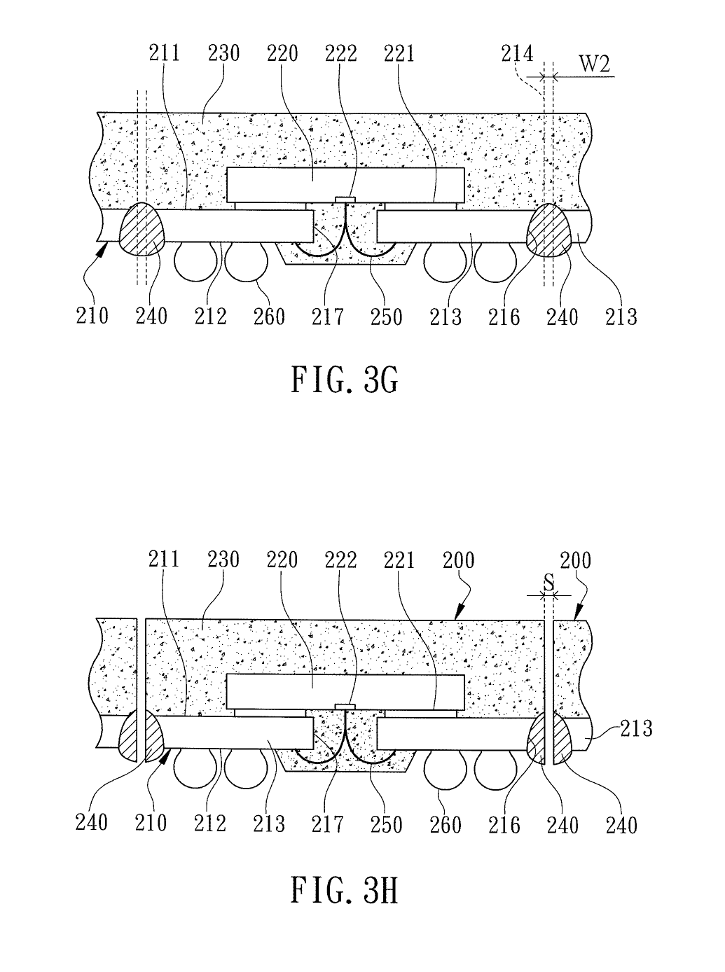

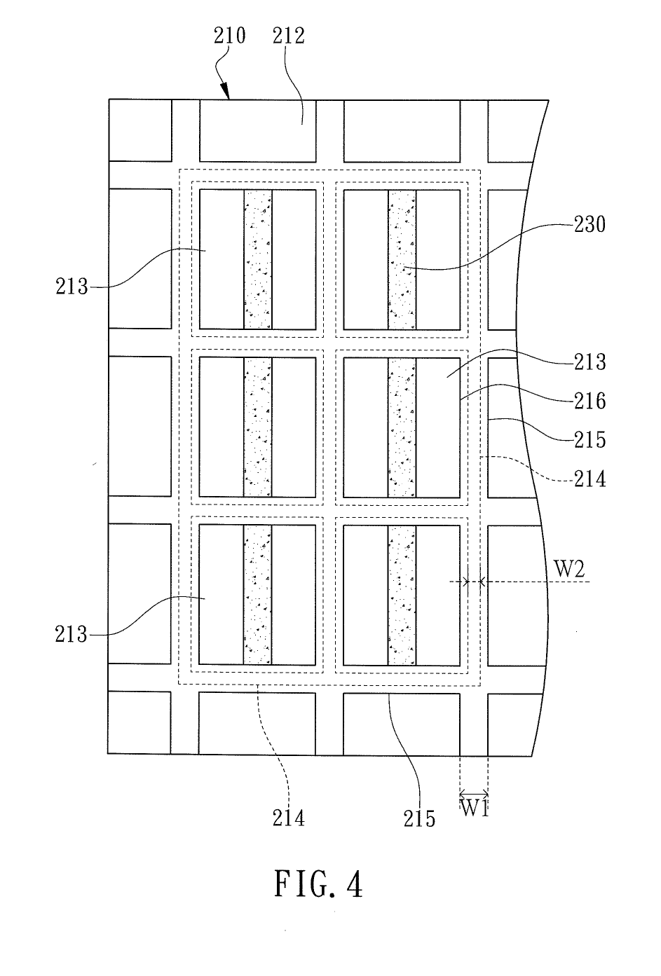

According to the first embodiment of the present invention, an MAP method to prevent exposure of substrate peripheries is illustrated in FIGS. 3A to 3H for component cross-sectional views in each processing step and FIG. 4 for a bottom view of a substrate strip after pre-cutting processes. The MAP method to prevent exposure of substrate peripheries is described in detail as follows.

Firstly, as shown in FIG. 3A, a substrate strip 210 is provided. The substrate strip 210 has a top surface 211 and an opposing bottom surface 212 where the top surface 211 is for the disposition of die attaching materials and molding compound and the bottom surface 212 is for the placement of a plurality of solder balls or other external terminals for SMT. Normally, the substrate strip 210 is a printed circuit board with single-layer or multi-layer metal circuitry for electrical interconnection where the substrate strip 210 also can be a flexible substrate or a ceramic substrate. As shown in FIG. 4, the substrate strip 210 includes a plurality of substrate units 213 as the chip carriers inside semiconductor packages 200. The dimension of each substrate unit 213 is corresponding to the dimension of a semiconductor package 200 as shown in FIG. 3H, i.e., one width of the substrate unit 213 as shown in FIG. 3A is the same as the width of the semiconductor package 200 in the same cross-section in FIG. 3H. A plurality of scribe lines 214 are defined between adjacent substrate units 213. The substrate units 213 are arranged in an array on the substrate strip 210 where each substrate unit 213 is rectangular or square. The substrate units 213 are integrally formed on the substrate strip 210 where alignment holes (not shown in the figure) are disposed at the peripheries of the substrate strip 210 for automation and alignment during the packaging processes. The scribe lines 214 include lateral scribe lines and vertical scribe lines defined between adjacent substrate units 213 but not parts of the substrate structures of semiconductor packages 200.

Then, as shown in FIG. 3B, a plurality of chips 220 are attached to the substrate units 213 on the top surface 211 which can be achieved by the existing die-attaching equipment and processes. The chips 220 can be Si, GaAs, or other semiconductor materials where various IC components are fabricated on the active surfaces 221 of the chips 220 such as DDR2, DDR3, DDR4 DRAM or non-volatile memory. The electrodes 222 are the external terminals of the internal circuitry of the chips 220 where the electrodes 222 are bonding pads made of Al or Cu or can be conductive bumps extruded from the active surface 221. The electrodes 222 can be disposed at one side, at two opposing sides, at peripheries, or at the center of the active surfaces 221 of the chips 220. Normally the chips 220 are disposed at the center of the corresponding substrate units 213. In the present embodiment, each substrate unit 213 has an attached chip 220 which is not limited where a plurality of chips 220 can be stacked on each substrate unit 213 as multi-chip packages (MCP). The chips 220 are attached to the corresponding substrate units 213 by doubt-sided PI tapes, liquid epoxy, pre-formed film, B-stage adhesive, or die-attach material (DAM). Furthermore, the active surfaces 221 of the chips 220 are attached to the top surface 211 of the substrate strip 210 as described in the present embodiment using window-type BGA packages as an example where a central slot 217 is formed at the center of each substrate unit 213 of the substrate strip 210 where the central slot 217 penetrates through the substrate strip 210 located at the center of each substrate unit 213. In the present embodiment, the electrodes 222 are disposed at the centers of the active surfaces 221 of the chips 220 where a plurality of electrodes 222 of the chips 220 are aligned to and exposed from the central slot 217 after die-attaching processes of the chips 220.

Then, as shown in FIG. 3C, the chips 220 are electrically connected to the substrate units 213. The step of electrical connection may includes forming a plurality of bonding wires 250 by wire bonding method where the bonding wires 250 pass through the central slot 217 to electrically connect the electrodes 222 of the chips 220 to the bonding fingers of the corresponding substrate unit 213. The bonding wires 250 are thin metal wires formed by wire bonding which can be gold or high conductivity metal materials such as Cu or Al to be electrical connection for signal transmission or power/ground plane connection between the chips 220 and the substrate units 213. But without any limitation, there are various electrical connections besides wire bonding to electrically connect the chips 220 to the substrate units 213 such as flip chip bonding, lead bonding and other well-known electrical interconnection.

Then, as shown in FIG. 3D, a first encapsulating material 230 is formed on the top surface 211 of the substrate strip 210 by molding processes to continuously encapsulate the substrate units 213 and the scribe lines 214, i.e., the encapsulating area of the first encapsulating material 230 is equal to or larger than the array area of the substrate units 213. Preferably, the first encapsulating material 230 further encapsulates the chips 220 to avoid external contamination. But without any limitation, the chips 220 can be bare chips with the back surfaces of the chips 220 exposed to the environment to further enhance heat dissipation. To be more specific, the first encapsulating material 230 can be an epoxy molding compound (EMC) having the physical properties of dielectric and thermosetting where the first encapsulating material 230 is formed by transfer molding or by other molding technology such as compression molding, printing, or spraying. Preferably, the first encapsulating material 230 is further formed inside the central slot 217 to encapsulate the bonding wires 250 during the formation of the first encapsulating material 230, therefore, the cut fragments or debris during the following pre-cutting processes will not be trapped inside the central slot 217 to avoid contamination of bonding wires 250. Moreover, the first encapsulating material 230 can be extruded from the bottom surface 212 of the substrate unit 213.

As shown in FIG. 3E and FIG. 4, a pre-cutting step is performed after the formation of the first encapsulating material 230 to form a plurality of cut grooves 215 along the scribe lines 214. The cut grooves 215 penetrate through the substrate strip 210 without penetrating through the first encapsulating material 230. Even though the substrate strip 210 has been cut through, the substrate units 213 along the chips 220 can integrally join together by the first encapsulating material 230 without falling apart. As specifically shown in FIG. 4, after pre-cutting processes, the width W1 of each cut groove 215 is wider than the corresponding width W2 of the scribe lines 214 so that the peripheries 216 of the substrate units 213 are exposed outside the scribe lines 214. To be more specific, the cut grooves 215 along the scribe lines 214 in lateral and vertical directions are connected to a plurality of peripheries of the substrate strip 210 with the width W1 of the cut grooves 215 wider than the width W2 of the corresponding scribe lines 214 as shown in FIG. 4. In other words, the portion of the substrate strip 210 in the scribe lines 214 are completely removed with the peripheries 216 of the substrate units 213 are not aligned in the scribe lines 214. To be described in more detail, the width of the cut grooves 215 is about 1.2 to 2 times wider than the width of the corresponding scribe lines 214. As shown in FIG. 3E again, the cut depth of the cut grooves 215 is deep enough to cut through the substrate strip 210 but without exceeding half of the thickness of the first encapsulating material 230 to form the cut grooves 215 like trenches. More detailedly, the thicknesses of the substrate strip 210 range from 0.08 mm to 0.3 mm. In one of the embodiments, the depth of the cut grooves 215 can be the same as or larger than the thickness of the substrate strip 210. The cut grooves 215 can be formed by laser drilling or by mechanical routing or by other methods with the same functions. For example, the cut grooves 215 can be formed by a cutting tool having a cutting route wider than the scribe lines 214 and a cutting depth deeper than the thickness of the substrate strip 210 to cut from the bottom surface 212 to the top surface 211. The cross-section of the cut grooves 215 can be rectangular, V-groove, curve, cone, funnel, or trapezoid with a narrowing base.

Then, as shown in FIGS. 3E and 3F, a second encapsulating material 240 is formed inside the cut grooves 215 to encapsulate the exposed peripheries 216 of the substrate units 213. To be more specific, the second encapsulating material 240 completely fills into the cut grooves 215 to ensure that all of the peripheries 216 of the substrate units 213 are not exposed. To be described in more detail, the composition of the second encapsulating material 240 can be the same as the one of the first encapsulating material 230 or includes different thermosetting resin such as underfilling materials with a better fluid property. In a different embodiment, the second encapsulating material 240 can be formed by printing or by dispensing besides the conventional transfer molding processes. Worth to be mentioned, a post-mold curing step can be performed after the formation of the second encapsulating material 240 to cure the first encapsulating material 230 and the second encapsulating material 240 at the same time to completely cure the encapsulating materials 230 and 240. Therefore, through the formation of the cut grooves 215 penetrating through the substrate strip 210 covering the scribe lines 214 after the first molding processes as a technical mean, the MAP method is simplified by using the post-mold curing step to completely cure the two encapsulating materials 230 and 240 at the same time.

To be more specific, as shown in FIG. 3G, a plurality of solder balls 260 are planted on the bottom surface 212 of the substrate strip 210 after formation of the second encapsulating material 240 and before singulation processes to be external terminals for SMT mounting to printed circuit boards. The solder balls 260 are arranged in an array so that more I/O interconnection can be accommodated in the same dimension of a substrate unit 213 to meet the requirement of high-density integration of semiconductor chips. However, without any limitation, in different embodiments, the solder balls 260 can be solder paste, contact pads, gold fingers, or contact pins.

Finally, a singulation step is performed. As shown in FIG. 3G and FIG. 3H, part of the first encapsulating material 230 on the scribe lines 214 and part of the second encapsulating material 240 inside the cut grooves 215 are removed to singulate the substrate units 213 to be individual semiconductor packages 200 with the peripheries 216 of the substrate units 213 being still encapsulated by the remains of the second encapsulating material 240. During the singulation step, only the first and second encapsulating materials 230 and 240 are cut without damaging the structure of the substrate units 213 to resolve the conventional exposure of the sidewalls of substrate units to avoid the exposure of metal traces and core layers at the peripheries of substrate units to further improve the resistant capability to the impact of environment such as oxidation, moisture, and others to improve the reliability of semiconductor packages. Furthermore, the substrate structure will not be damaged during singulation processes to avoid the deformation or shifting of internal circuitry inside the substrate due to the stresses caused by cutting through thick substrates during singulation processes.

To be more specific, as shown in FIG. 3E again, since the width of the scribe lines 214 is smaller than the width of the cut grooves 215, the width of the gap S formed after removing the first encapsulating material 230 and the second encapsulating material 240 as shown in FIG. 3H is the same as the width W2 of the scribe lines 214 as shown in FIG. 3G so that both sides of the cut grooves 215 are not cut, i.e., the peripheries 216 of the substrate units 213 will not be damaged during the singulation processes. Therefore, the peripheries 216 of the substrate units 213 in each individual semiconductor package 200 are still encapsulated by the singulated second encapsulating material 240 to avoid the exposure of metal traces and core layers at the peripheries 216 of substrate units 213 to further improve the resistant capability to the impact of environment such as oxidation, moisture, and others to improve the reliability of semiconductor packages.

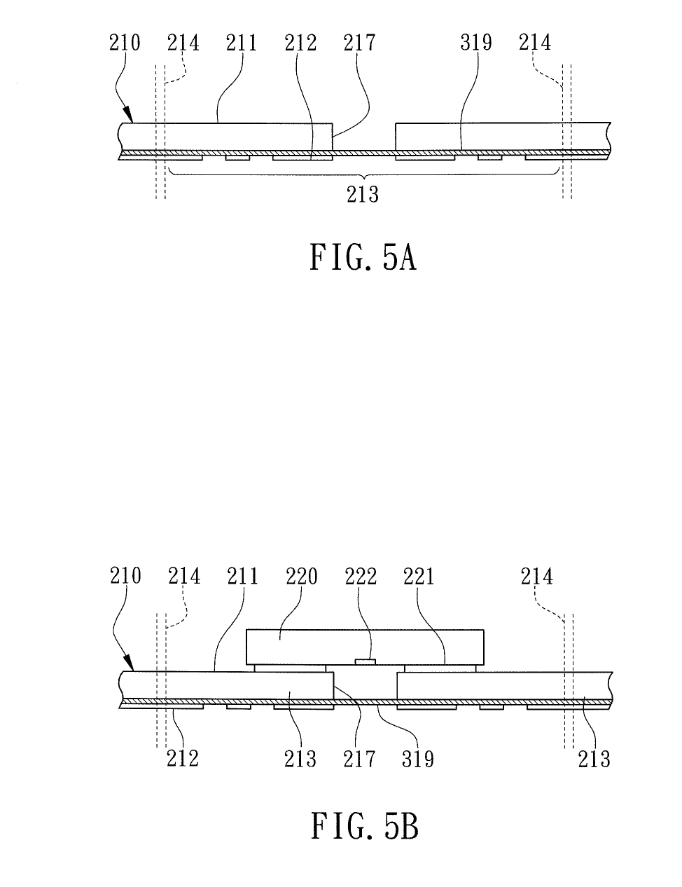

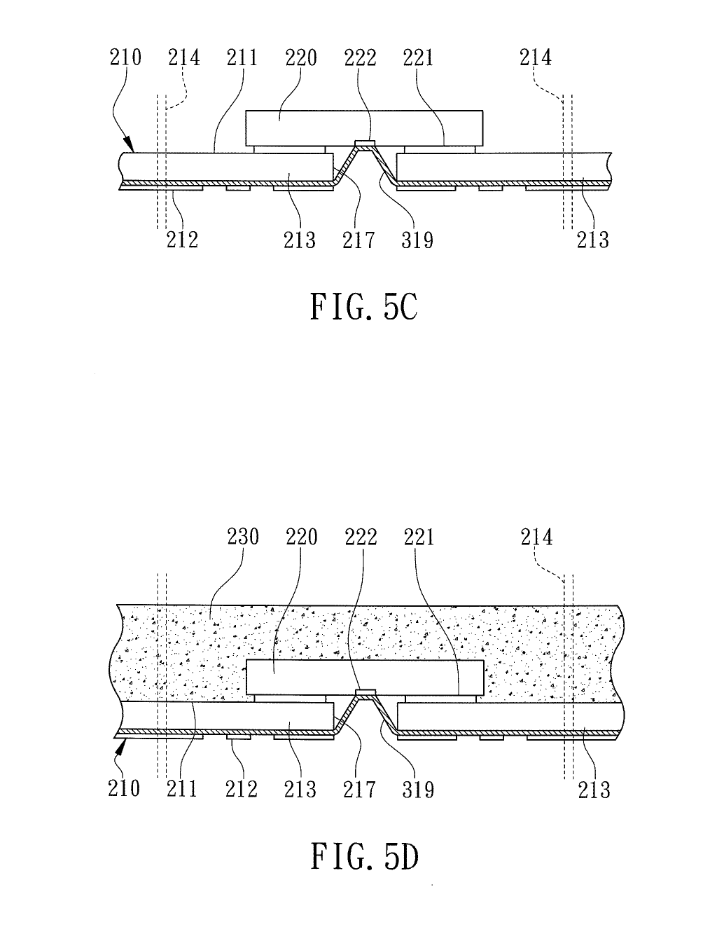

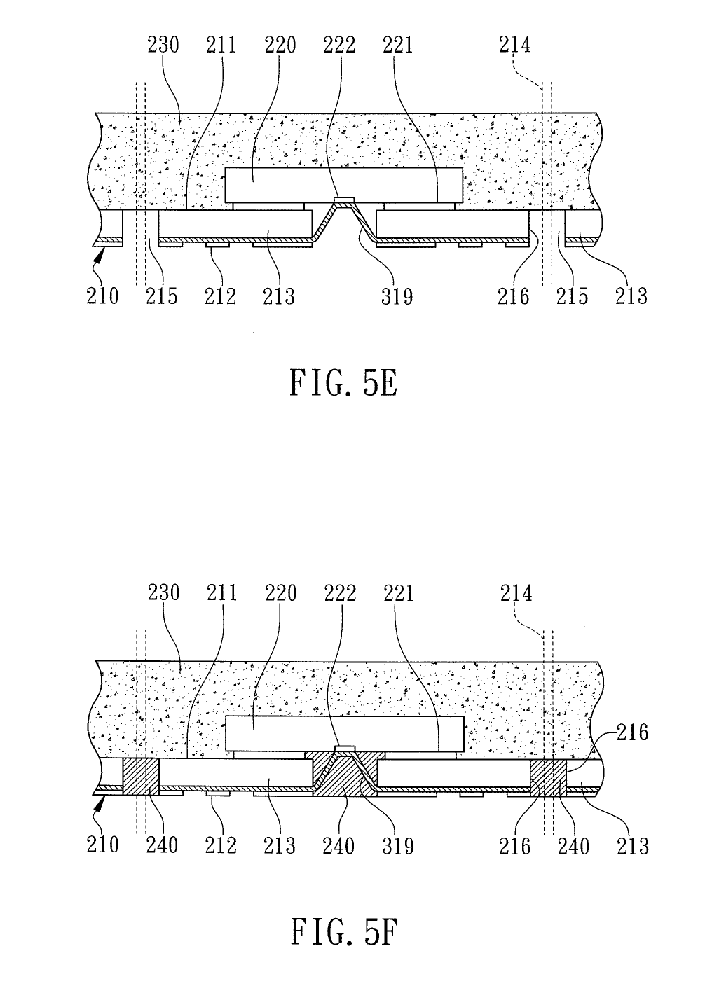

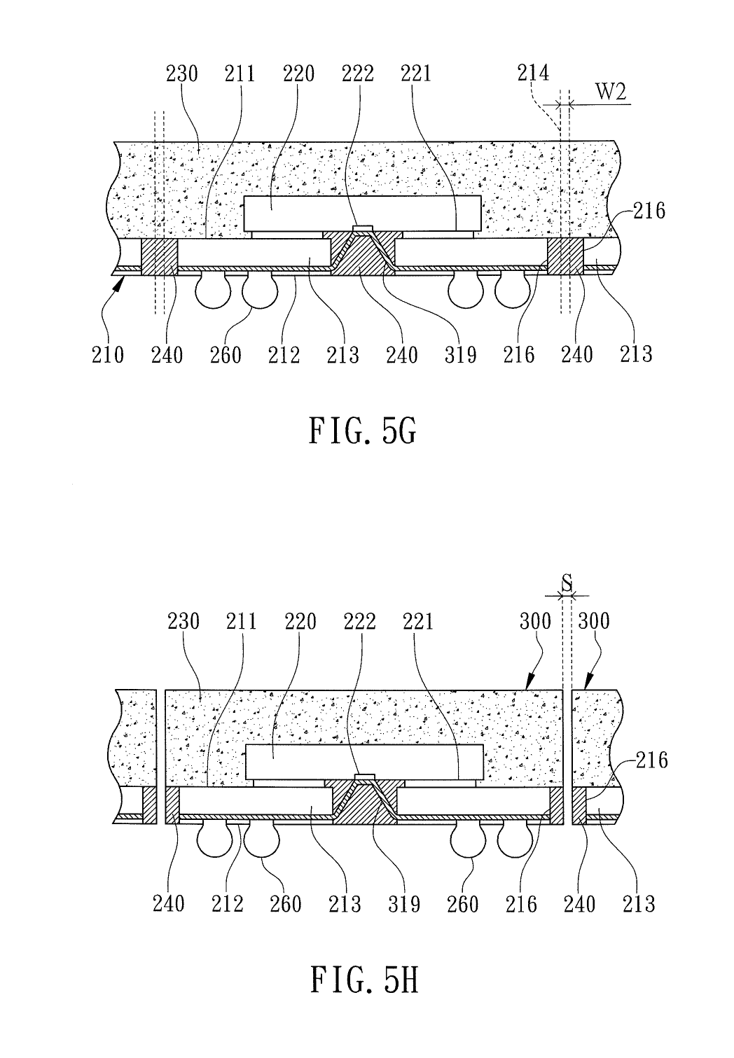

Another MAP method to prevent exposure of substrate peripheries is disclosed in the second embodiment of the present invention. The component cross-sectional views in each processing step are illustrated from FIG. 5A to FIG. 5H where the major components with the same functions are illustrated with the same notations and numbers which will not be described in detail herein.

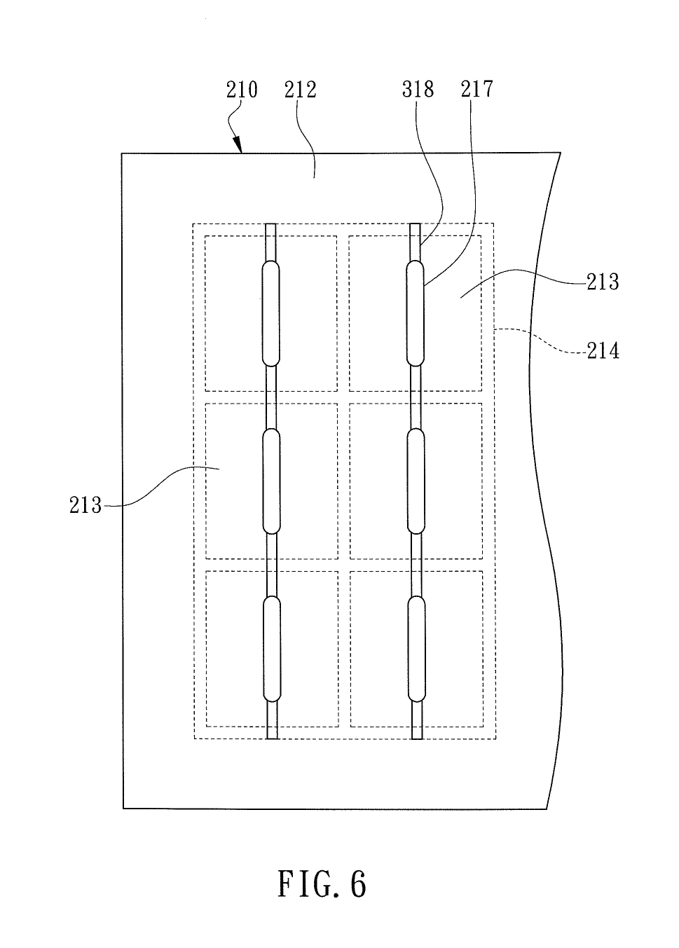

Firstly, as shown in FIG. 5A and FIG. 6, a substrate strip 210 is provided. In the present embodiment, the substrate strip 210 further includes a plurality of inner leads 319 besides the internal circuitry where the inner leads 319 may be the extension of the internal circuitry of the substrate strip 210 or additional suspended leads which are normally copper traces with plated finish formed by etching metal foils such as copper foils or by plating on conductive foils to become flexible. Each substrate unit 213 has a central slot 217. The inner leads 319 suspend over the central slots 217 before the processing step of electrical connection.

Then, as shown in FIG. 5B, a plurality of chips 220 are disposed on the top surface 211 within the substrate units 213 with the electrodes 222 of the chips 220 aligned to and exposed from the central slots 217. Then, as shown in FIG. 5C, the chips 220 are electrically connected to the substrate units 213 where the inner leads 319 of the substrate strip 210 are bonded to the electrodes 222 of the chips 220 by breaking the inner leads 319 at the pre-breaking points and passing through the central slots 217 by an ILB bonding head. Comparing to electrical connection by wire bonding, electrical connection by the inner leads 319 has shorter signal transmission paths without loop height and without metal jointing interfaces at two bonding ends of bonding wires which is most suitable for high-speed semiconductor packages.

Then, as shown in FIG. 5D, a first encapsulating material 230 is formed on the top surface 211 of the substrate strip 210 by molding to continuously encapsulate the substrate units 213 and the scribe lines 214 to avoid external contamination.

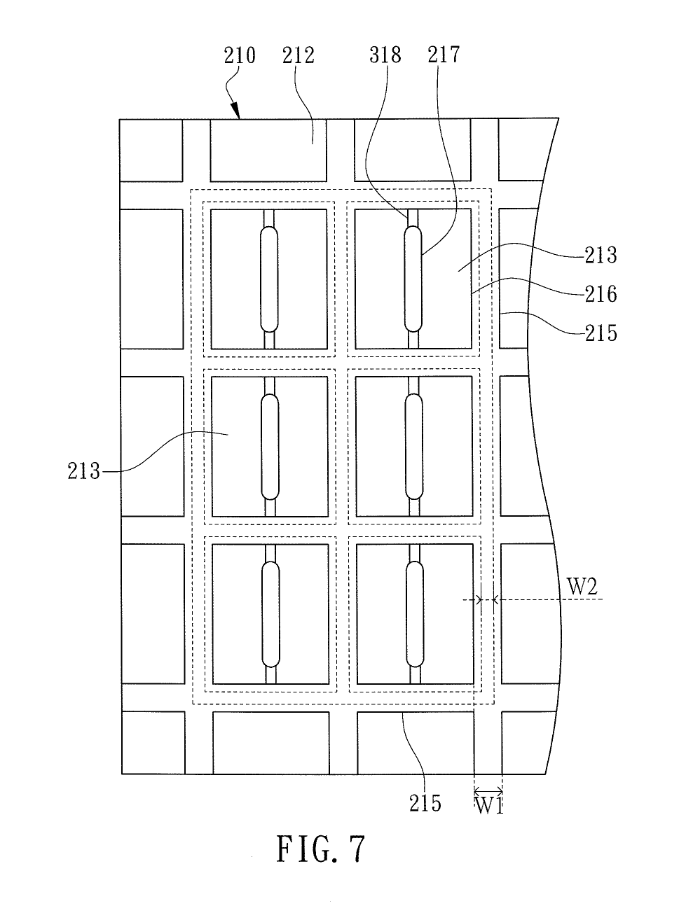

Then, as shown in FIG. 5E and FIG. 7, a pre-cutting step is performed after the formation of the first encapsulating material 230 to form a plurality of cut grooves 215 along the scribe lines 214. The cut grooves 215 penetrate through the substrate strip 210 without penetrating through the first encapsulating material 230. The width W1 of each cut groove 215 is wider than the width W2 of the corresponding scribe line 214 so that the peripheries 216 of the substrate units 213 are exposed outside the scribe lines 214. In the present embodiment, as shown in FIG. 5E, the depth of the cut grooves 215 can be the same as the thickness of the substrate strips 210 without cutting to the first encapsulating material 230 where the cross-section of the cut grooves 215 can be rectangular. To be more specific, as shown in FIG. 7 again, the cut grooves 215 are formed to completely cover the scribe lines 214 and extend in lateral and vertical directions of the scribe lines 214 until to the edges of the substrate strip 210 to ensure that the peripheries 216 of the substrate units 213 are not located within the scribe lines 214. Moreover, preferably, the substrate strip 210 further has a plurality of connecting grooves 318 formed on the bottom surface 212 connecting the central slots 217 to the cut grooves 215 where the connecting groove 318 does not penetrate through the substrate strip 210 with the cutting depth not deeper than the one of the cut grooves 215. The connecting grooves 318 can be formed in the step of providing the substrate strip 210 or in the pre-cutting step.

Then, as shown in FIG. 5E and FIG. 5F, a second encapsulating material 240 is formed inside the cut grooves 215 to encapsulate the peripheries 216 of the substrate units 213 where the second encapsulating material 240 completely fills into the central slot 217 to encapsulate the inner leads 319 in the forming step. Preferably, the second encapsulating material 240 can be directed to the central slot 217 through the connecting grooves 318 connected to the cut grooves 215 so that the connecting grooves 318 are filled with the second encapsulating material 240 as inner runners. In a specific embodiment, the encapsulating height of the second encapsulating material 240 can not exceed the bottom surface 212 of the substrate strip 210. Accordingly, the second encapsulating material 240 can be formed by flat molding.

Then, as shown in FIG. 5G, a plurality of solder balls 260 are planted on the bottom surface 212 of the substrate strip 210 after formation of the second encapsulating material 240 and before singulation processes to be external terminals for SMT mounting to printed circuit boards.

Finally, as shown in FIG. 5G and FIG. 5H, part of the first encapsulating material 230 on the scribe lines 214 and part of the second encapsulating material 240 inside the cut grooves 215 are removed by singulation to singulate the substrate units 213 to be individual semiconductor packages 300 with the peripheries 216 of the substrate units 213 are still encapsulated by the remains of the second encapsulating material 240. During the singulation step, only the first and second encapsulating materials 230 and 240 are cut without damaging the structure of the substrate units 213 to resolve the conventional exposure of the sidewalls of substrate units, to avoid the exposure of metal traces and core layers at the peripheries of substrate units, and to further improve the resistant capability to the impact of environment such as oxidation, moisture, and others to improve the reliability of semiconductor packages.

The above description of embodiments of this invention is intended to be illustrative but not limited. Other embodiments of this invention will be obvious to those skilled in the art in view of the above disclosure which still will be covered by and within the scope of the present invention even with any modifications, equivalent variations, and adaptations.

What is claimed is:

1. An MAP method to prevent exposure of substrate peripheries comprising:
providing a substrate strip having a top surface and an opposing bottom surface, the substrate strip including a plurality of substrate units in an array and a plurality of scribe lines defined between the substrate units, wherein the dimension of each substrate unit is corresponding to the dimension of a semiconductor package;
disposing a plurality of chips on the substrate units;
electrically connecting the chips to the substrate units;
forming a first encapsulating material on the top surface of the substrate strip by molding to continuously encapsulate the substrate units and the scribe lines;
performing a pre-cutting step to form a plurality of cut grooves penetrating through the substrate strip along the scribe lines without penetrating through the first encapsulating material, wherein the cut grooves have a width wider than the width of the scribe lines so that each substrate unit has a plurality of exposed peripheries outside the scribe lines;
forming a second encapsulating material inside the cut grooves to encapsulate the exposed peripheries of the substrate units; and
performing a singulation step to remove part of the first encapsulating material disposed on the scribe lines and part of the second encapsulating material disposed inside the cut grooves to singulate the substrate units into individual semiconductor packages with the peripheries of the substrate units still encapsulated by the remains of the second encapsulating material.

2. The MAP method as claimed in claim 1, wherein the substrate strip further has a central slot formed in each substrate unit, wherein a plurality of active surfaces of the chips are attached to the substrate units on the top surface with a plurality of electrodes of the chips aligned to and exposed from the central slots during the step of disposing the chips.

3. The MAP method as claimed in claim 2, wherein the second encapsulating material completely fills into the central slots during the step of formation of the second encapsulating material.

4. The MAP method as claimed in claim 3, wherein the substrate strip further has a plurality of connecting grooves on the bottom surface connecting the central slots to the cut grooves.

5. The MAP method as claimed in claim 4, wherein the encapsulating height of the second encapsulating material doesn't exceed the bottom surface of the substrate strip.

6. The MAP method as claimed in claim 2, wherein the first encapsulating material further fills inside the central slots during the step of formation of the first encapsulating material.

7. The MAP method as claimed in claim 2, wherein the step of electrical connecting the chips and the substrate units includes forming a plurality of bonding wires by wire bonding passing through the central slot to electrically connect the electrodes of the chips to the substrate units.

8. The MAP method as claimed in claim 2, wherein the step of electrical connecting the chips and the substrate units includes bonding a plurality of inner leads suspending over the central slots on the substrate strip to the electrodes of the chips by passing through the central slots.

9. The MAP method as claimed in claim 1, further comprising a step of planting a plurality of solder balls on the bottom surface of the substrate strip after the step of formation of the second encapsulating material and before the singulation step.

10. The MAP method as claimed in claim 1, wherein the width of the removed gaps of the first encapsulating material and the second encapsulating material during the singulation step is the same as the width of the scribe lines.

11. The MAP method as claimed in claim 1, further comprising a post-mold curing step to cure the first encapsulating material and the second encapsulating material at the same time after the step of the formation of the second encapsulating material and before the singulation step.

12. The MAP method as claimed in claim 1, wherein the cut grooves along the scribe lines in lateral and vertical directions are connected to a plurality of edges of the substrate strip.

13. The MAP method as claimed in claim 1, wherein the cut grooves have a depth the same as the thickness of the substrate strip

14. The MAP method as claimed in claim 1, wherein the cut grooves have a depth greater than the thickness of the substrate strip.

15. The MAP method as claimed in claim 14, wherein the depth of the cut grooves doesn't exceed half of the thickness of the first encapsulating material.
